(19) United States
(12) Patent Application Publication
(10) Pub. No.: US 2005/0076943 A1
(43) Pub. Date: Apr. 14, 2005

(54) Thermoelectric sensor

(76) Inventors: Jon Cooper, Glasgow (GB); Erik Andrew Johannessen, Glasgow (GB)

Correspondence Address: DANN, DORFMAN, HERRELL & SKILLMAN, 1601 MARKET STREET, SUITE 2400, PHILADELPHIA, PA, 19103-2307, US

(21) Appl. No.: 10/497,842

(22) PCT Filed: Dec. 9, 2002
(86) PCT No.: PCT/GB02/05572

(30) Foreign Application Priority Data
Dec. 7, 2001 (GB) 0129288.7

(51) Int. Cl. H01L 35/28

(52) U.S. Cl. 136/224

(57) ABSTRACT

A thermoelectric sensor for monitoring biological samples is provided, the sensor comprising a substrate (26) having a plurality of thermocouple sensing junctions (18) arranged circularly about a central region, a number of reference junctions (30) arranged about the sensing junctions (18), and a low thermal mass air cavity (32) provided adjacent to the sensing junctions. A heating element (16) may also be provided. The sensor of the invention may be used to monitor temperature changes from individual cells or groups of cells, or from biologically active compounds or samples, as a result of biological activity. The sensor may thus be used for screening candidate drugs and the like.

The present invention relates to a miniaturised sensing system for the measurement of thermal changes in biological samples. In certain embodiments, the invention relates to a sensor for the measurement of relatively small thermal changes in small-scale samples, such as individual cells or groups of cells. Further aspects of the invention relate to a method of manufacturing such a sensor, and to a method of assaying thermal changes in biological samples.

At present a number of techniques are in use for assaying the biological activity of cells and biological systems (such as cell-free systems and the like). These assays are particularly used in the biomedical and pharmaceutical industries for the identification and testing of candidates for potential new drugs and the like. In these industries, it is of interest that the assays be suitable for high-throughput applications, to assay multiple compounds or samples in as little time as possible, and also that the assays be relatively sensitive, since even a slight effect may be sufficient to make a candidate drug worthwhile pursuing.

Typical techniques which are used in assaying biological activity include expression profiling of mRNA expression, or the use of fluorophores to indicate antibody binding, calcium modulation, or other intracellular messaging mechanisms. However, while these assays may be sensitive, they are often relatively specific, and require some knowledge of the activity of the compound under test to select an appropriate assay. It is therefore of interest to develop an assay of more general application.

One characteristic of biological systems which may be of general application is the generation of thermal energy by any biological activity., Changes in the metabolic activity of a biological system will result in a quantitative change in the thermal energy generated by that system; a thermal assay may therefore be used to identify biological activity of a test compound without requiring any knowledge of the possible pathways of activity of the test compound. In fact, thermal assays in the form of thermal imaging techniques and the like have been used for gross measurements on the scale of a whole organism, or of a tissue or the like. However, such current assays are not of sufficient sensitivity, and nor do they exist in the correct formats, to reliably detect and distinguish the small-scale changes in thermal energy experienced by small samples (for example, single cells). Further, existing thermal assays being applied to large-scale samples (such as whole organisms) are unsuitable for the high-throughput, rapid screening requirements demanded by the biomedical or pharmaceutical industries.

It is among the objects of embodiments of the present invention to obviate or alleviate these and other disadvantages of conventional assays. It is further among the objects of certain embodiments of the present invention to provide an assay system which may be used for high-throughput screening of small biological samples such as isolated cells.

This is achieved in part in certain embodiments of the invention by providing a miniaturised thermal sensor with a reduced thermal mass by comparison to conventional sensors, thereby increasing the sensitivity of the sensor and allowing measurement of relatively small changes in thermal activity.

According to a first aspect of the present invention, there is provided a thermoelectric sensor for monitoring biological samples, the sensor comprising a substrate having a plurality of thermocouple sensing junctions formed thereon, the sensing junctions being arranged about a central region, corresponding thermocouple reference junctions coupled to the sensing junctions, and a region of relatively low thermal mass provided adjacent at least that portion of the substrate bearing the sensing junctions.

The geometry of the sensing junctions of the present invention thus enables a number of sensing junctions to be provided in a relatively small area, of a size compatible with measurement of biological samples in a lab-on-a-chip or microsystem format. Similarly, the number of sensing junctions provided allows increased sensitivity of the sensor compared to prior art sensors of similar dimensions.

The provision of a low thermal mass region adjacent the substrate bearing the sensing junctions serves to insulate the junctions from the environment, thereby improving the sensitivity of the sensor, and the response time. This advantage allows a sensor of the invention to measure such small-scale changes in temperature as are experienced by small numbers of cells or other biological samples in real time, measurements which are not possible with prior art sensor arrangements.

‘Biological samples’ may refer to individual cells or small groups of cells; tissue samples; cell-free extracts; cell organelles; or may refer to isolated biochemical materials, such as enzymes or components of biochemical pathways. It is intended that the sensor of the present invention be suitable for measurement of microscopic or submicroscopic samples, such as individual cells or the like.

Preferably the sensing junctions are arranged to cover an area of less than around 30 μm². This is of a size compatible with measurement of single or few biological cells.

Preferably the sensing junctions are arranged in a generally circular layout around a central region. Such an arrangement provides an optimal or near-optimal sensing junction density to area ratio, by maximising the possible number of sensing junctions in the sensing region, so improving the sensitivity of the sensor. Preferably the sensing junctions are spaced from the centre of the central region by a distance compatible with the size off a sample appropriate to lab-on-a-chip analysis, such as a single cell; conveniently the sensing junctions are spaced around 5 to 15 microns from the centre of the central region; preferably the spacing is around 10 microns. The sensing junctions are preferably of relatively small length, to allow cells to be comfortably located over a junction; conveniently therefore the sensing junctions are around 2 to 10 microns in size; preferably around 5 microns. The reference junctions may also be provided in a circular arrangement around the central region; a greater distance will typically separate the reference junctions from the central region to remove the reference junctions from the range of the environment being sensed at the sensing junctions.

Conveniently around 5 to 15 sensing junctions are provided; in a preferred embodiment, 10 sensing junctions are provided. It will be apparent to the skilled person, however, that the number of junctions provided may be varied without departing from the scope of the invention, and will generally be selected on practical grounds.

Preferably the junctions are formed of dissimilar metals; suitable metals include for example palladium—gold, or nickel—gold. Other suitable metals will be known to those of skill in the art. In a preferred embodiment, the junctions are nickel—gold junctions.

Preferably the sensor further comprises a heating element for calibration of the sensor. Conveniently the heating element is located adjacent the sensing junctions. Where the sensing junctions are arranged circularly about a central region, preferably the heating element is located within the central region.

Preferably the region of low thermal mass comprises a gas-filled cavity; preferably an air cavity. The cavity is preferably substantially sealed, to restrict flow of gas therein, so improving the insulating properties of the cavity.

Preferably the reference junctions are distanced from the region of low thermal mass. Conveniently, for example, the reference junctions may be disposed adjacent a material surrounding the region of low thermal mass.

Preferably the substrate comprises a membrane. Preferably at least the portion of the substrate adjacent the low thermal mass region comprises a membrane; this ensures that the effect of the substrate on heat transfer between a sample and the low thermal mass region will be minimised. The remainder of the substrate may be in the form of a membrane also; or may be substantially thicker, for example, to form the boundaries of the low thermal mass region. Preferably the membrane is less than 2 microns in thickness; more preferably less than 1 micron; and most preferably less than 800 nm. Preferably the sensing junctions are formed on the membrane. Conveniently the membrane comprises a silicon compound; preferred materials include silicon nitride (Si₃N₄). The boundaries of the low thermal mass region may be formed from the same material as the membrane; preferably however an alternative material is used. A preferred embodiment of the invention has the boundaries of the low thermal mass region formed of bulk silicon.

Preferably the sensor further comprises a titre chamber defining a region including the sensing junctions. Preferably the chamber is of relatively low volume; preferably below 2 nL; more preferably below 1 nL; most preferably below 700 pL. The titre chamber is preferably defined by a polymer deposited adjacent the thermocouple elements; preferably the polymer covers the reference junctions and does not cover the sensing junctions. This arrangement serves to further isolate the reference junctions from the sensing junctions. Conveniently the chamber is defined by a generally circular opening within the polymer. Conveniently the opening has a diameter of around 200 microns. Conveniently the opening has a depth of around 25 microns. Preferably the polymer is biocompatible. Preferably the polymer is photopatternable. In preferred embodiments of the invention, the polymer is a polyimide. Conveniently, the polymer may be PDMS (polydimethylsiloxane), or SU-8. The polymer may further comprise channels, chambers, or other areas defined therein to allow movement of fluids therealong. For example, the polymer may define a number of channels leading from reagent chambers to the titre chamber, so allowing reagents to be added to a sample within the titre chamber where desired. The sensor may thus further comprise means for moving fluids along such channels or chambers; for example, microelectrodes or nanoscale pumps may be used to move fluids.

Preferably the sensing junctions are coated to improve biological cell adhesion thereto; for example, the junctions may carry a coating of poly-L-lysine. Other possible coatings will be apparent to those of skill in the art, and may be selected with reference to the purpose for which the sensor is to be used.

Preferably the sensor further comprises a biochemically active compound located on the thermocouple sensing junctions. This allows the sensor to be used to detect activity of the compound which would generate or absorb heat, such as chemical reactions. Conveniently the active compound is a catalyst; most preferably the compound is an enzyme. Such a sensor with an enzyme may be used to detect the presence of the enzyme substrate in a test sample, or the like.

According to a second aspect of the present invention, there is provided a thermoelectric sensor array comprising a plurality of thermoelectric sensors, each sensor comprising a substrate having a plurality of thermocouple sensing junctions formed thereon, the sensing junctions being arranged about a central region, corresponding thermocouple reference junctions coupled to the sensing junctions, and a region of relatively low thermal mass provided adjacent at least that portion of the substrate bearing the sensing junctions.

The sensors may be provided on a common substrate.

Preferably the array is provided in a microtitre plate format; for example, a 96-well plate format. This ensures compatibility with existing molecular biological equipment, and allows high-throughput analysis of multiple samples simultaneously. Higher multiples of 96-well plate formats may also be used; for example, 384-well, 864-well, or 1536-well plate formats. Of course, the invention need not be restricted to microtitre plate formats.

The array may further comprise fluid channels, chambers, or the like, to allow delivery of fluid reagents and so forth to each sensor.

According to a further aspect of the present invention, there is provided a thermoelectric sensor comprising a substrate having a plurality of thermocouple sensing junctions formed thereon, the sensing junctions being arranged about a central region, corresponding thermocouple reference junctions coupled to the sensing junctions by electrical tracks extending radially outwardly of the central region from the sensing junctions, and a region of relatively low thermal mass provided adjacent at least that portion of the substrate bearing the sensing junctions.

Preferably the sensing junctions and reference junctions are arranged circularly about the central region. The central region may also contain a heating element.

According to a further aspect of the present invention, there is provided a method of manufacturing a thermoelectric sensor for monitoring of biological samples, the method comprising the steps of:
forming a plurality of sensing and reference junctions on a membrane located on a support; and
removing a part of the support adjacent the sensing junctions to leave a membrane bearing the sensing junctions overlying a region of lower thermal mass.

Preferably the method further comprises the step of depositing a membrane on the support prior to forming the sensing and reference junctions thereon. The membrane may be deposited by any suitable means. Alternatively, the support used in the method of the invention may be provided ready-coated with a suitable membrane.

The membrane is preferably a silicon compound, more preferably silicon nitride (Si₃N₄). The support is preferably silicon. The membrane and support are preferably of different materials.

Preferably the junctions are formed by deposition. Conveniently the junctions are formed by metal deposition; which may include electron beam evaporation.

Suitable materials include gold—nickel. Formation of the junctions may further comprise. photolithography or electron beam lithography to define detailed features of the junctions. Preferably the sensing junctions are provided in a generally circular arrangement about a central region.

The step of removing a part of the support may comprise back etching the support in a defined region. The support may be back etched by means of an alkali; preferably potassium hydroxide. Removal of the support is preferably restricted to leave a membrane of around 800 nm thickness.

The method may further comprise the step of mounting a cover to the support to substantially enclose the region of lower thermal mass.

The method may further comprise the step of depositing a substance over the junctions to form a titre chamber around the sensing junctions. The substance is conveniently a polymer, preferably a biocompatible polymer, preferably a photopatternable polymer, and conveniently a polyimide. The substance may be photopatterned to define the chamber. Additional features may be incorporated into the substance, such as channels, chambers, and the like for storage and movement of fluids therealong.

The method may further comprise the step of coating the sensing junctions with a substance to promote cell adhesion thereto; for example, poly-L-lysine.

The method may further comprise the step of coating the sensing junctions with a biochemically active substance. Conveniently the substance is a catalyst, and more preferably the substance is an enzyme.

The method may further comprise the step of manufacturing additional sensors on a common support, to form a sensor array. The array is preferably in a microtitre dish format, such as a 96-well plate format.

A number of sensors may be manufactured on a common support, and the support subsequently separated to provide individual sensors.

According to a still further aspect of the present invention, there is provided a method of screening test compounds for physiological effects on a biological sample, the method comprising the steps of:
locating a biological sample on a thermoelectric sensor comprising a substrate having a plurality of thermocouple sensing junctions formed thereon, the sensing junctions being arranged about a central region, corresponding thermocouple reference junctions coupled to the sensing junctions, and a region of relatively low thermal mass provided adjacent at least that portion of the substrate bearing the sensing junctions;
contacting the biological sample with a test compound; and
monitoring thermal properties of the biological sample before and after contact, to determine any difference between the two states, a difference being indicative of a physiological effect of the test compound on said biological sample.

Preferably the biological sample comprises one or more cells. The cell or cells may be vertebrate, are preferably mammalian, and are most preferably human.

The cells may comprise a group of cells taken from a biopsy sample.

Additional components may be combined with the cell or cells; for example, growth medium, any necessary biological factors, signalling molecules, and the like, or biological material such as blood serum, lymph, and so forth.

According to a further aspect of the present invention, there is provided a method of high-throughput screening of test compounds for physiological effects on biological samples, the method comprising:
locating one or more biological samples on each of a plurality of thermoelectric sensors forming an array, each sensor comprising a substrate having a plurality of thermocouple sensing junctions formed thereon, the sensing junctions being arranged about a central region, corresponding thermocouple reference junctions coupled to the sensing junctions, and a region of relatively low thermal mass provided adjacent at least that portion of the substrate bearing the sensing junctions;
contacting a test compound with each of the biological samples; and
monitoring thermal properties of the biological samples before and after contact, to determine any difference between the two states, a difference being indicative of a physiological effect of the test compound on said biological sample.

Additional sensors may be present in the array which do not have biological samples located thereon.

Conveniently the biological samples *comprise one or more cells.

The test compound may be identical for each biological sample tested; or may vary between sensors.

The biological sample may be of identical type for each sensor, or different types of biological sample may be tested simultaneously.

According to a still further aspect of the present invention, there is provided a method of monitoring the physiological activity of a biological sample, the method comprising the steps of:
locating a biological sample on a thermoelectric sensor, the sensor comprising a substrate having a plurality of thermocouple sensing junctions formed thereon, the sensing junctions being arranged about a central region, corresponding thermocouple reference junctions coupled to the sensing junctions, and a region of relatively low thermal mass provided adjacent at least that portion of the substrate bearing the sensing junctions; and
monitoring thermal energy generated by the sample, the energy being indicative of physiological activity.

These and other aspects of the present invention will now be described by way of example only and with reference to the accompanying drawings, in which:

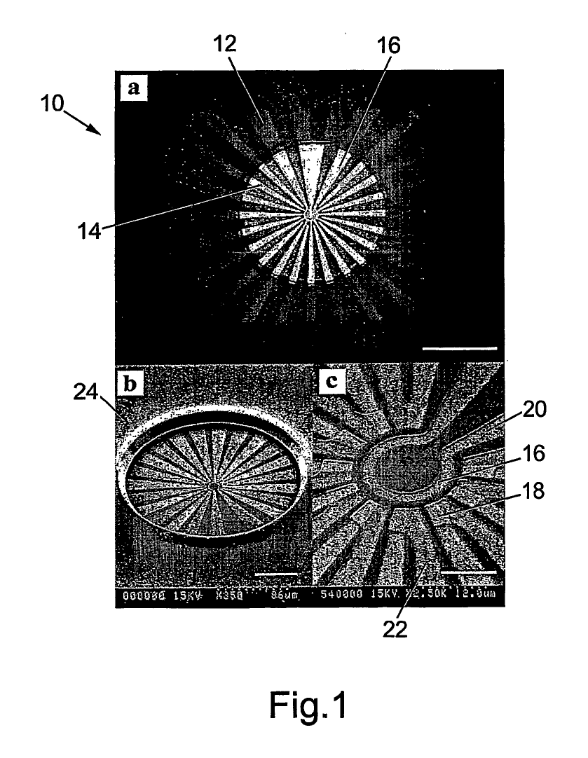

FIG. 1 shows a thermroelectric sensor in accordance with an embodiment of the present invention. FIG. 1a shows a photomicrograph of the sensor from above; FIG. 1b shows a scanning electron micrograph of the sensor; and FIG. 1c shows a scanning electron micrograph of the sensing junctions of the sensor;

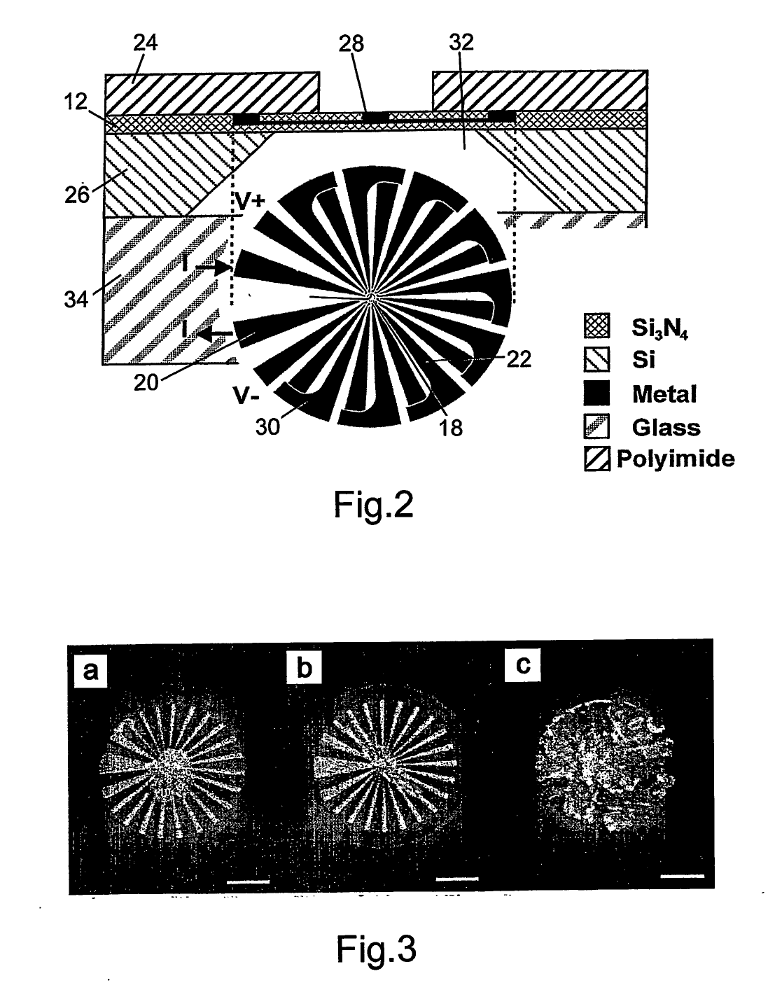

FIG. 2 shows a cross sectional view of the sensor of FIG. 1, in combination with a plan view of the thermocouple arrangement;

FIGS. 3a to 3c show photomicrographs of the sensor of FIG. 1 having cells located thereon. FIG. 3a shows a cluster of ten brown adipocytes; FIG. 3b shows a single cardiomyocyte; and FIG. 3c shows a group of twenty cardiomyocytes located on the sensor;

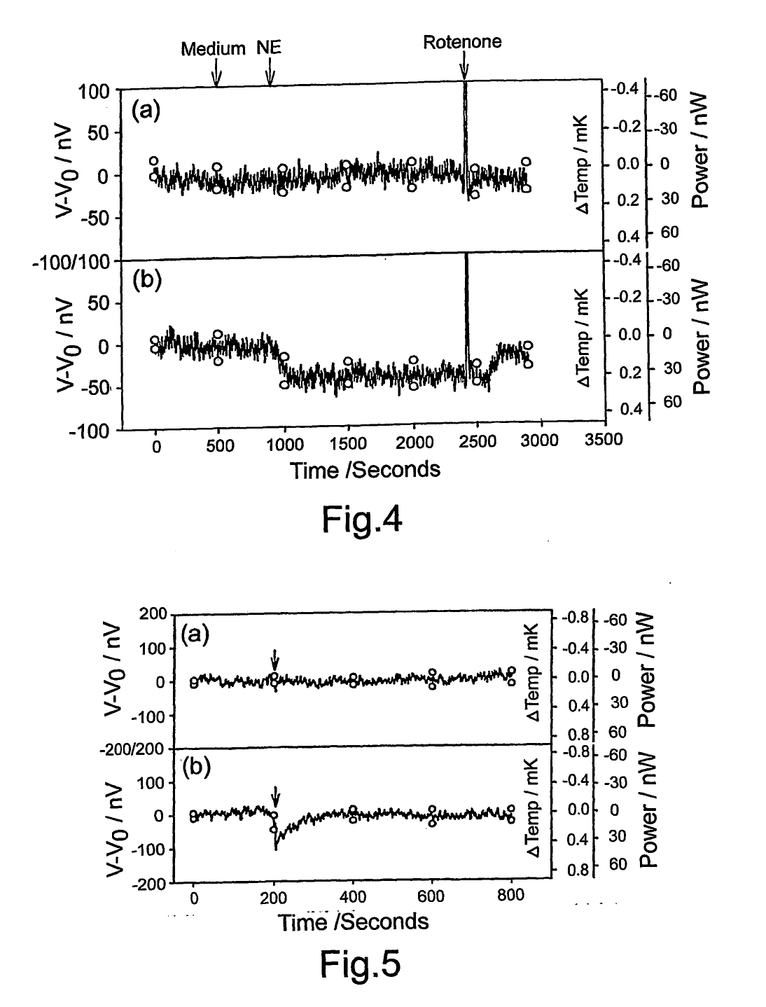

FIG. 4 shows representative data of thermogenic response from 10 cultured brown adipocytes on addition of 1.4 μM noradrenaline (NE). The downward deflection of the trace indicates generation of heat. The signal change is presented as V-V₀ on the left axis (representing the voltage (V) with respect to the background voltage (V₀) at time=0). The values on the right axis correspond to the absolute temperature change ΔT) and power generation (nW) respectively. All injections were of 10 pL, with concentrations adjusted appropriately. Culture medium was injected at 900 s as a control before the injection of 1.4 μM NE (dissolved in culture medium) at 1300 s and 14 μM rotenone (dissolved in acetonitrile) at 2400 s. Panel a shows the average of 5 control experiments with no cells in the sensor. Panel b shows the average response from 5 experiments, each from a group of approximately 10 cells. The error bars (open circles) represent the standard error of the mean (SEM).

FIG. 5 shows heat production from the hydrolysis of 14 μM H₂O₂ (arrow) by native catalase located within a single mouse liver cell. The average signal from no cells is shown in panel a. The average signal from a single liver cell is shown in panel b. The downward deflection of the trace indicates generation of heat. The error bars (open circles) represent the standard error of the mean (SEM, n=3).

Referring first of all to FIGS. 1 and 2, these show a thermoelectric sensor 10 in accordance with an embodiment of the present invention. FIG. 1a is a photomicrograph (scale bar represents 100 μm) showing a 300 by 300 μm membrane of silicon nitride (Si₃N₄, indicated ,by reference numeral 12) supporting ten radially arrayed nickel-gold thermocouple elements 14 positioned around a central calibration heater element 16.

As may be clearly seen in FIG. 1c (a scanning electron micrograph of the central region of the sensor 10, with the scale bar representing 10 μm), the heater element 16 is surrounded by thermocouple sensing junctions 18 of the thermocouple elements, each measuring 5×3 μm. The heater element 16 is served by a pair of electrically conducting tracks 20. Each of the thermocouple elements 14 includes a sensing junction 18 located adjacent the heater element 16 and covering a circular area 30 μm in diameter, and a reference junction (not shown), located some 250 μm from the centre, and which is an integral part of the device. Each thermocouple element includes electrically conducting tracks 22 which extend radially outward from the sensing junctions in the centre to the reference junctions.

FIG. 1b (a scanning electron micrograph, scale bar represents 50 μm) shows the sensor 10 includes a layer of polyimide 24 some 25 μm in thickness, and defining a cell chamber 200 μm in diameter about the centre of the sensor 10. The reference junctions are located beneath the polyimide layer 24.

The structure of the sensor 10 is shown more schematically in FIG. 2, which shows a cross section of the sensor 10, combined with a plan view of the thermocouple elements. The sensor 10 includes a silicon substrate layer 26 on which is disposed the membrane 12 of Si₃N₄. On the membrane 12 is formed the thermocouple arrangement 28, which is also shown in plan view, to illustrate the heating element 16 with its electrical connections 20, the sensing junctions 18, and the reference junctions 30, connected by the electrical tracks 22.

Beneath the membrane 12 is formed an air pocket 32, etched from the silicon substrate 26, and sealed with a layer of glass 34.

Having described the structure of the sensor 10, the present document will now proceed to describe the method of manufacture of the sensor, and a number of experiments conducted therewith to demonstrate its capabilities.

Materials and Methods

Brown adipocytes. Brown adipose tissue (BAT) was dissected from the interscapular, subscapular and the axillary regions of four 4-week-old male Naval Medical Research Institute (NMRI) mice. Pre-adipocytes were isolated and seeded in three 30 mm culture dishes and incubated in medium containing sodium bicarbonate (3.7 g/l) under 8% CO₂ atmosphere for 6 days, after which time they were harvested. The culture medium based on DMEM with pH 7.4, was modified with 10% foetal calf serum, 20 nM insulin, 1 nM triiodothyronin (T₃), 25 μg/ml Na-ascorbate, 4 mM glutamine, 10 mM HEPES, 50 IU/ml penicillin and 50 μg/ml streptomycin. Insulin was required for the expression of mitochondrial uncoupling protein (UCP) whereas the presence of T₃ increased the thermogenic response due to more β-adrenergic receptors on the cells. All chemicals were supplied from Sigma-Aldrich and ICN Biomedicals Inc.

Cardiomyocytes. Isolated cells were obtained from adult rabbit left ventricle by collagenase digestion and kept in Base Krebs Solution, containing: 120 mM NaCl, 20 mM sodium N-hydroxyethylpiperazine-N′-2-ethane sulphonic acid (HEPES), 5.4 mM KCl, 0.52 mM NaH₂PO₄, 3.5 mM MgCl₂.6 H₂O, 20 mM taurine, 10 mM creatine, 11.1 mM glucose, 0.1% bovine serum albumin (BSA), pH 7.4. Cells were transferred to the sensor chips using a pipette (manual or robotic instrument) and placed onto the thermocouple junctions.

Fabrication of the thermoelectric sensor. The thin film thermopile constructed from 10 thermocouples was made by metal deposition of gold and nickel onto single-crystal 3″ (7.62 cm) silicon wafers pre-coated with 30 nm silicon nitride (Si₃N₄). The wafer was spin-coated with PMMA resist and patterned directly using electron beam lithography to define the two metal layers of gold and nickel. Flash-coating of a 10 nm adhesive layer of nickel chromium (NiCr) was required to bond the gold and nickel to Si₃N₄. The metals were deposited in 50 and 100 nm thick layers respectively by electron beam evaporation. The bonding pads were patterned using photolithography before the whole wafer was covered with an insulating layer of 800 nm plasma enhanced chemical vapour deposited (PECVD) Si₃N₄ with the pads opened up using dry etching with C₂F₆. An additional layer of 10 nm NiCr was also required to assist adhesion of the 23 μm thick layer of polyimide defining the walls of the cell chamber. Both steps were patterned using photolithography. Finally the wafer was back etched in 8.1 M potassium hydroxide (KOH) revealing a 800 nm thick membrane of pure Si₃N₄ under the thermopile sensing junctions. A custom-made wafer holder protected the micromachined front side from the KOH solution.

The fabrication protocol was developed in such a manner that device production could readily be scaled-up. Thus, 80 sensors were simultaneously fabricated on a single wafer using silicon micromachining. The chips were then diced up in individual units of 5×5 mm and bonded on to a glass holder with epoxy resin and connected using a wire bonder with 25 μm thick gold wires. The attachment sealed off the space of air under the sensor membrane creating an air pocket offering excellent insulation both from within the system and from the surrounding air.

Low noise amplifier. Low-noise, chopper-stabilised operational amplifiers, CS3001, were donated by Cirrus Logic Corporation and incorporated into the low noise preamplifier. The input voltage noise with the thermoelectric sensor connected was 55 nVₚₚ from DC to 1 Hz, corresponding to a spectral density of 9.2 nV/√Hz. The gain was set at 100,000 and the offset voltage was around 250 nV in all experiments. The sensitivity of measurements, determined as 3 standard deviations above noise (27.5 nV), corresponded to an ability to resolve a 125 μK temperature change. Averaging of n experiments further increased the experimental sensitivity by √n to e.g. 12.5 nV or 60 μK (n=5) which is the resolution of the trace in FIG. 4.

Experimental Set-up: The sensor chip used in the experiment (FIG. 1) was connected to the custom-made low noise preamplifier, which was positioned within 1 cm of the sensor chip in order to reduce attenuation of the voltage signal and minimise interference. The chip-holder was connected to the amplifier through a gold plated 2.54 mm (0.1 inch) pitch PCB edge connector (gold was used consistently in all contacts to avoid the creation of additional thermocouple junctions between the sensor output and the amplifier input). A transparent chamber enclosed the sensor from the surrounding air to eliminate rapid temperature changes. Water (37° C. or 25° C.), maintained at a constant temperature, was circulated through a 1 ml chamber integrated as part of the copper base plate. Both amplifier and sensor were positioned under a stereo-microscope for the manipulation and positioning of cells, injection of drugs and visual observation throughout the experiment,. The attachment of cells on the thermopile was enhanced by pre-treating the sensor surface with poly-L-lysine, adsorbed from a 0.01% solution in buffer.

The cell chamber was first covered with a 0.5 μL drop of culture medium with a subsequent addition of 15 μL liquid paraffin (mineral oil) in order to prevent evaporation of the medium. Re-suspended adipocytes (or cardiomyocytes) were positioned on top of the sensing junctions using a micropipette and micromanipulator (FIG. 3a, b, c). Excess medium was removed from the titre chamber leaving a total volume of 700 pL. The sensor chip was then connected to the amplifier, sealed by the polystyrene chamber and placed( under the microscope. Three back filled glass capillaries with culture medium, 0.1 mM NE and 1.0 mM rotenone respectively were, in turn, mounted on the micromanipulator and inserted into the cell chamber for microinjection. Rotenone was insoluble in aqueous solutions at these relatively high concentrations, and the compound was consequently introduced in acetonitrile. Appropriate control experiments were performed to show that the response was not due to mixing of the solvent. Likewise, for cardiomyocytes a capillary containing 1.0 mM CCCP (dissolved in ethanol) was used, with a comparable series of controls to ensure the attribution of the recorded response to a change in cellular activity.

Experiment 1: Cell-Based Assays

Microsystem Characterisation.

In order to theoretically relate the temperature from the calibration heater to the heat generated from a group of cells situated above the thermopile, the microsystem was modelled with a partial differential equation solver (“Pdease 2.53”; SPDE Inc.) using finite element analysis.

For a known calibrant heat input, the sensing junctions were found to give a voltage response over a linear dynamic range up to 200 nW (mV/G=2.12 nW, r=0.97, where G is the amplifier gain, 10⁵), enabling the use of the device in a range of systems including enzymic titrations as well as individual cells and tissue measurements. The results showed good agreement with the modelled response. This was further corroborated experimentally by biochemical titrations into the 700 pL titre chamber, using the exothermic enzyme catalysed activity of catalase in the presence of hydrogen peroxide. From these experimental data, the microsystem was found to have a very good temperature sensitivity of 125 μK, a time factor of 12 ms, a heat conductance of 105 μW/K and a low thermal mass, giving a heat capacity of 1.2 μJ/K. The device has a detection limit, defined as the signal three standard deviations above the mean of the background, thereby enabling measurements with a resolution of 13 nW from either enzymic or cellular systems.

Cell Based Measurements

Cell-based measurements initially focused on brown adipocytes, which play an important role in thermoregulatory heat production in “nonshivering thermogenesis” in mammals. Brown fat cells are unique in that they generate heat from uncoupled mitochondria by expressing mitochondrial uncoupling protein (UCP) which decouples respiration from oxidative phosphorylation and which ensures that the cells maintain a high respiratory capacity and heat production. The investigation of brown adipose tissue is important in the study of obesity and a variety of pathologies, including fever and trauma. This cell type is of particular interest as it has previously been used in a pharmaceutical toxicity screen for assessing the action of new pharmaceuticals on mammalian cells.

In our Microsystems technology, we have been able to use cells isolated directly as primary cultures (in this example, immature differentiated brown adipocytes). These cells have the advantage that they have a similar thermogenic capacity and a lower lipid content, when compared with fully matured adipocytes. The lower buoyancy of the immature cell (whose density is greater than that of the culture medium) facilitates their attachment to the sensor and enables a good thermal contact, see FIG. 3a.

Measurements of heat output from cells were made with the cell chamber filled with 700 pL of culture medium and overlain with a layer of mineral oil to prevent evaporation. The device was held at a constant temperature of either 25° C. or 37° C. In the absence of cells there was no response from the thermopile to the injection of 10 pL of culture medium, nor to 10 pL culture medium containing a final concentration of 1.4 μM NE (see FIG. 4). Thermogenic responses of cells were observed at decade changes of concentrations of NE and were compared both with cellular basal heat production. For example, introduction of NE into the chamber at a final concentration 1.4 μM (which gave a “saturated” thermogenic response) resulted in a rapid rise in heat production, with the maximum value recorded within ca. 2 min. The magnitude of the response was consistent with published values from populations of cells, where above-threshold levels of NE activation induced a ten-fold increase in oxygen consumption.

Heat output from NE-stimulated cells appeared to be sustained for at least 20 minutes (FIG. 4). Mitochondrial activity was then inhibited by adding rotenone to the chamber at a final concentration of 14 μM. The large initial peak resulted from the heat of dissolution of acetonitrile used as a solvent (see Methods section above). There was subsequently a 3 minute delay, reflecting the time for dissipation of the mitochondrial proton gradient, before the temperature response returned to basal level within 5 mins (FIG. 4). Cell death, observed by extensive blebbing of the cell membrane, occurred between 1 and 5 minutes later but no further fall in signal was detected. The thermogenic responses from groups of 10 NE-stimulated cells corresponded to an average power output of 16.3 nW or 1.63 nW per cell (n=5). Again, this is consistent with published values from tissues, which range from an averaged heat production of 0.4 nW per cell, measured using microcalorimeters, to 5 nW per cell, based on the oxygen consumption of tissue in vivo.

In order to demonstrate the generic nature of the assay, measurements were also made of the heat output from isolated cardiac myocytes, challenged with the mitochondrial uncoupler carbonyl cyanide m-chlorophenyl hydrazone (CCCP). Uncoupling of the mitochondria is believed to be important in cardiac pathology and this technique is an established protocol for developing an in vitro model for the ischaemic cell. Experiments were carried out using a variety of cell numbers ranging from single cells to groups of multiple cells, FIG. 3b, c. Accordingly, rabbit ventricular cardiomyocytes, exposed to CCCP (final concentration of 14 μM), showed a mean change in signal of 136 μK within three minutes, equivalent to the production of 1.71 nW per cell (n=5). This value is comparable with published data on multicellular heart biopsies which gave calorimetric values for uncoupled myocardial tissue equivalent to 710 mW/g dry weight, estimated as 1.42 nW per cell.

Experiment 2: Biochemical assays

The performance of the nanocalorimeter was evaluated by enzymic titrations of bovine liver catalase with H₂O₂. The hydrolysis of H₂O₂ is extremely exothermic with an enthalpy change of −100 kJ/mol. The activity of catalase was considered at room temperature (25° C.) at pH 7. Stock solutions from 100 to 2000 U/ml were prepared for the 60 pL sample, by dissolution of catalase in phosphate buffer (pH 7). The corresponding enzyme activity ranged from 6 to 120 μU in the suspension volume, with an associated peak power output from the sample of 10 to 200 nW in the presence of 10.5 mM H₂O₂.

The catalase suspension was microinjected into the nanocalorimeter pre-covered with liquid paraffin to prevent sample evaporation before connection to a DC to 1 Hz electronic voltage amplifier with a sensitivity of 27.5 nV, thus giving the calorimeter a temperature sensitivity of 125 μK. The device was then enclosed within a small polystyrene chamber for improved thermal insulation. The injection volume of catalase was estimated from the perfect hemispherical shape of the droplet observed under the microscope with a base radius of 30 μm. Hydrogen peroxide (˜10.5 mM) was then microinjected (4.2 pL) into the catalase suspension by inserting a micropipette preloaded with H₂O₂ (150 mM) through a small slot in the polystyrene chamber. The maximum response (nV) were recorded as a function of power (nW) with the enzyme catalysis measured over a period from 2 to 14 seconds related to the catalase activity. The linear regression from the experimental data (mV/G=2.46 nW, r=0.97, where G is the amplifier gain, 10⁵) suggested a responsivity of 2.46 nV/nW from the sample, corresponding to a heat conductance of 90 μW/K and a heat capacity of 1.1 μJ/K of the device. Correlating the responsivity of the nanocalorimeter with the sensitivity of the electronic amplifier, the detection limit for the system from a 60 pL sample was 11.2 nW.

The experiment was repeated for a 700 pL volume of catalase suspension with activities ranging from 5.8 to 2330 U/ml occupying the entire reaction chamber. The associated peak power output from the 700 pL sample would range from 7 to 2800 nW upon microinjection of H₂O₂ (10 pL) resulting in an initial concentration of 14 mM. The linear regression from the experimental data (mV/G=1.14 nW, r=0.94, where G is the amplifier gain, 10⁵) suggested a responsivity of 1.14 nV/nW from the catalase solution, corresponding to a heat conductance of 190 μW/K and a heat capacity of 2.3 μJ/K of the device. The heat conductance and heat capacity of the larger reaction volume reduced the detection limit of the device to 24.1 nW.

It was clear that the sensitivity of the nanocalorimeter depends on the size of the heat generating sample present in the reaction vessel. The results were supported by modelling the system with a partial differential equation solver (SPDE Inc., USA) using finite element analysis. The modelled responsivity of 2.99 nW/nV for the 60 pL volume and 1.10 nW/nV for the 700 pL volume was within 20% of the experimental results. The simulation was also employed to theoretically relate the temperature from the 60 pL catalase sample to the heat generated from a single mouse liver cell situated above the thermopile. The volume of the cell (˜5 pL) was too small to recreate experimentally. The culture medium (pH 7.4) required to accommodate the cell occupied the full volume of the reaction vessel, and was considered to have the same thermodynamic properties as water. Thus the modelled responsivity supported a value of 2.75 nV/nW, with a corresponding detection limit of 10 nW. The heat conductance for a single cell system would be 80 μW/K with a heat capacity of 1 μJ/K.

Subsequently a mouse liver cell was positioned by a micromanipulator and immobilised on top of the temperature sensors in the reaction vessel with the aid of Cell-Tak tissue adhesive ensuring good thermal contact between the cell and sensor surface. H₂O₂ was then microinjected to yield an initial concentration of 14 mM after 200 seconds of the experiment commencing. The signal response is given in FIG. 5. The slightly altered pH value of the medium has minimal effect on the catalase activity. No significant signal change from the mixing of solutions was observed in the empty system (no cells) used as a control. In contrast, the maximum signal change in the experimental trace (a negative signal corresponds to heat evolution) was translated to 38.2 nW of generated power. The hydrolysis of 10.1 pmol H₂O₂ (14 mM, 700 pL) corresponding to an energy production of 1010 nJ of heat, was within 50% of the experimental value integrating the triangular area defined by the signal from 200 to 300 s. The short time constant for thermal equilibrium of the sensor (12 ms) compared to the long time duration of the measured signal (100 s), excludes a temperature difference in the injected solution as the cause of the measured temperature change. The corresponding enzyme activity of 24 μU/cell is consistent with average literature values, which estimate activities of 0.15 μU to 250 μU/cell from studies using multicellular preparations.

Conclusions

Temperature measurements offer a generic approach to primary cell-based assays and have a capability to screen libraries of bioactive compounds, particularly where the cellular actions, signalling pathways or suitable probes are either not known or not available. There is the clear ability to gain toxicity data from such screens. The present experiments demonstrate the feasibility of implementing a novel method for monitoring temperature changes in isolated mammalian cells, presenting data which consistently shows good correlations with experimental values obtained using multicellular preparations. The technology has been implemented in a Microsystems format, with a demonstrated ability to be integrated in a lab-on-a-chip methodology. It has the clear potential to be used in multiple screens of cells isolated from a single organ or biopsy, thereby reducing inherent variations between animals and enhancing the quality of data sets.

Miniaturisation of this thermal sensing technology provides a number of potential advantages including extreme sensitivity (enabling use of biopsy tissue or isolated cells); low volume assays (appropriate for screening library compounds); faster assays (due to reduced diffusion distances and the immediacy of the heat response); and finally ease of manufacturing (using methods adapted from the semi-conductor industries). The technology has the added advantage that it does not require the use of recombinant or genetically modified cells, nor the development or introduction of specific probes into the cell, in order to be able to determine changes in cellular response.

Additional applications

The thermal sensor as described herein may be used for a number of different applications, some of which may require slight modifications of the particular example structure described. Brief details of a number of possible uses are described below.

Use of the device in an array for high throughput. Batch fabrication allows for the integration of multiple sensors on a common substrate, preferably silicon compatible with the developed Microsystems technology. An automated process such as robotic manipulation may be used for sample injection, combined with surface modification of the sensor to retain, when cells are used, optimum location on top of the sensing junctions of the thermopile transducer. Separate electronic input channels will be required for data analysis from each thermoelectric sensor by the data acquisition instrument.

Potential drug interactions with proteins, ligands or receptors in combinatorial screening. Drug interactions with enzymes, ligands or receptors is accompanied with a direct change in heat upon the binding to ligands and receptor molecules, or as an indirect change in heat as a result from the stimulating or inhibitory action on an enzyme catalysed process. The appropriate assay is injected into the system and the temperature monitored upon injection of the pharmacological agent. This can be used for a variety of assays including those for receptors and ligand binding.

Alternatively immunochemical analysis can be achieved by immobilising immunosorbents (preferably antibodies) inside the titre chamber. The pharmacological antigen to be determined is labelled with an enzyme, and introduced into the chamber. The solution is then changed and the level of antigen bound to the antibodies is measured indirectly as a function of heat production after subsequent introduction of substrate. In this way the binding between antigen and antibodies, which normally produce small amounts of heat, can be detected indirectly by the heat generating action from the labelled enzyme.

Protein crystallisation studies. Crystallisation of molecules is one of several means (including aggregation/precipitation) by which a metastable supersaturated solution can reduce the overall free energy by reduction of solute concentration. The crystal shape is dependent on the structural nature of the macromolecule, which is of interest for molecular biologists, with the size of the crystals dependent on the speed and overall temperature of the crystallisation process. Both the total quantity of heat released, and the speed of the crystallisation process, can be determined by applying the microsystem to protein crystallisation studies. Chemical precipitants can be used to achieve supersaturation of macromolecules and induce crystallisation at various speeds from uncontrolled instantaneous crystallisation to a controlled process lasting several days. Saturated solution of dissolved protein is first injected into the titration chamber. The chemical precipitant (for example, MPEG 5000/NaCl) is then injected to precipitate the crystallisation.

Following chemical synthetic pathways in combinatorial synthesis. The rapid simultaneous synthesis of different chemical compounds from low cost starting materials is known as combinatorial synthesis, and has accelerated the number of potential targets for testing in pharmacological research. The chemical reactions required to synthesise new compounds are normally accompanied with an enthalpy change, where the process absorbs heat from the surrounding environment. Thus the identification of chemical synthetic pathways can be associated with a specific quantity of heat absorbed. The starting materials (reagents) are injected into the titration chamber and heated up with the power from the heater and corresponding temperature change in the system simultaneously monitored. Thus any change in temperature without an accompanying change in the power input from the heater reflects the synthesis of the reagents. The microsystem is then cooled down and the synthetic compound (product) analysed. The integration of the device for high throughput synthesis would be possible by adapting similar methodology to high throughput screening.

Clinical diagnostics. Immobilisation of cells sensitive to antigens in the blood and which respond to the presence of antigen by an increase in heat production, such as human neutrophils, can be integrated in the system for use in clinical diagnostics. The increase in heat is an excellent measure of activated phagocytotic cells and it is likely that the heat profile will differ both qualitatively and quantitatively depending on the nature of the triggering agent.

Higher or lower metabolic rates due to pathological changes or xenobiotic induced alterations in the cell can be detected by measuring the metabolism of cells taken from biopsies compared to control groups of healthy cells. The detection of cancer or the physiological effect from medication may be monitored this way.

The glucose levels in a liquid, such as blood, can be monitored by immobilising an enzyme catalysing glucose to gluconolactone, such as glucose oxidase, in a region on top of the sensing junctions of the thermopile. A secondary enzyme, such as catalase, which catalyses the production of hydrogen peroxide, which is a by-product of the oxidation of glucose, should be co-immobilised. The additional heat released from the exothermic reaction of the catalysis of hydrogen peroxide is detectable by the temperature sensor indirectly as a function of glucose concentration.

Environmental diagnostics. The immobilisation of eukaryotic cells, micro-organisms, or multiple enzyme systems could be used to provide a general detection method of bioactive materials, such as pesticides, inhibitors, and poisonous materials in the environment. The measurement of the inhibitory or stimulating action directly as a reduction or increase in the metabolic rate of the cells or the catalytic activity of the enzymes may be monitored as the change in heat production. Thus the measurement of heat is indirectly proportional to the level of bioactive materials.

Enzymes inhibited or acting directly on a specific compound can be immobilised in the sensor for higher specificity. For example, urease may be used to detect heavy metals such as mercury. Rhodanese may be used to detect toxins such as cyanide. Preferably enzymes whose activity is not permanently inhibited, but is restored after washing, should be used. Enzymes acting directly on pesticides and esterase inhibitors could also be used.

Gas sensing. The microsystem can be adapted to a gas sensor, by measuring the heat of absorption to a gas sensitive material. Alternatively, the combustion of gas mixtures by modifying the titration chamber to a sealed gas reaction chamber can be achieved. The combustible gases are introduced into the reaction chamber through two inlet channels and ignited by powering the internal heater to the flash point of combustion. The heat released in the combustion process is recorded by the thermopile sensor. The products of the combustion are removed through an outlet channel. The small quantity of combustible gases used increases the safety of the operator, and reduces the use of potentially expensive and hazardous chemicals.

Molecular biology—PCR amplification. The microsystem is equipped with an integrated heater, temperature sensors, and reaction chamber, which makes it suitable for conversion to a sub-nL volume PCR reactor upon integration with an adequate external temperature control circuit. Details of the PCR (polymerase chain reaction) process are well known. The low time factor of 12 ms of the thermal sensor will allow for rapid thermal cycling reducing the time for amplification of the required PCR products. The low heat conductance of 190 μW/K of the microsystem would require only 18 mW of power to reach a temperature of 96° C., allowing battery operation for a portable PCR device. The relatively large thermal mass of the supporting bulk silicon (16.6 mJ/K) should provide an adequate heat sink compared to the heat capacity of the reaction chamber (2.3 μJ/K). Alternatively, the bulk silicon could be clamped to an external heat sink for more rapid heat transfer and thermal cycling.

1. A thermoelectric sensor for monitoring biological samples, the sensor comprising a substrate having a plurality of thermocouple sensing junctions formed thereon, the sensing junctions being arranged about a central region, corresponding thermocouple reference junctions coupled to the sensing junctions, and a region of relatively low thermal mass provided adjacent at least that portion of the substrate bearing the sensing junctions.

2. The sensor of claim 1, wherein the sensing junctions are arranged to cover an area of less than around 30 μm2.

3. The sensor of claim 1, wherein the sensing junctions are arranged in a generally circular layout around a central region.

4. The sensor of claim 3, wherein the sensing junctions are spaced from the centre of the central region by a distance compatible with the size of a sample appropriate to lab-on-a-chip analysis, such as a single cell.

5. The sensor of claim 4, wherein the sensing junctions are spaced around 5 to 15 microns from the centre of the central region.

6. The sensor of claim 1 wherein the sensing junctions are around 2 to 10 microns in size.

7. The sensor of claim 1, wherein the reference junctions are provided in a circular arrangement around a central region.

8. The sensor of claim 1, wherein around 5 to 15 sensing junctions are provided.

9. The sensor claim 1, wherein the junctions are formed of dissimilar metals.

10. The sensor of claim 9, wherein the junctions are nickel-gold junctions.

11. The sensor of claim 1, wherein the sensor further comprises a heating element for calibration of the sensor.

12. The sensor of claim 11, wherein the heating element is located adjacent the sensing junctions.

13. The sensor of claim 1, wherein the region of low thermal mass comprises a gas-filled cavity.

14. The sensor of claim 13, wherein the cavity is an air cavity.

15. The sensor of claim 13, wherein the cavity is substantially sealed to restrict flow of gas therein.

16. The sensor of claims 1, wherein the region of low thermal mass comprises a cavity under a vacuum.

17. The sensor of claim 1, wherein the reference junctions are distanced from the region of low thermal mass.

18. The sensor of claim 17, wherein the reference junctions are disposed adjacent a material surrounding the region of low thermal mass.

19. The sensor of claim 1, wherein the substrate comprises a membrane.

20. The sensor of claim 19, wherein at least the portion of the substrate adjacent the low thermal mass region comprises a membrane.

21. The sensor of claim 19, wherein the membrane is less than 2 microns in thickness.

22. The sensor of claims 19, wherein the sensing junctions are formed on the membrane.

23. The sensor of claims 19, wherein the membrane comprises a silicon compound.

24. The sensor of claim 23, wherein the membrane comprises silicon nitride (Si₃N₄).

25. The sensor of claim 1, further comprising a flow channel defining a region including the sensing junctions.

26. The sensor of claim 1, further comprising a titer chamber defining a region including the sensing junctions.

27. The sensor of claim 26, wherein the chamber is of relatively low volume.

28. The sensor of claim 27, wherein the chamber has a volume below 2 nL.

29. The sensor of claims 25, wherein the titer chamber or flow channel is defined by a polymer deposited adjacent the thermocouple elements.

30. The sensor of claim 29, wherein the polymer covers the reference junctions and does not cover the sensing junctions.

31. The sensor of claim 29 wherein the polymer is photopatternable.

32. The sensor of claim 29, wherein the polymer further comprises channels, chambers, or other areas defined therein to allow movement of fluids therealong.

33. The sensor of claim 32, further comprising means for moving fluids along the channels or chambers.

34. The sensor of claim 1, wherein the sensing junctions are coated to improve biological cell adhesion thereto.

35. The sensor of claim 1, further comprising a biochemically active compound located on the thermocouple sensing junctions.

36. The sensor of claim 35, wherein the active compound is an enzyme.

37. A thermoelectric sensor array comprising a plurality of thermoelectric sensors, each sensor comprising a substrate having a plurality of thermocouple sensing junctions formed thereon, the sensing junctions being arranged about a central region, corresponding thermocouple reference junctions coupled to the sensing junctions, and a region of relatively low thermal mass provided adjacent at least that portion of the substrate bearing the sensing junctions.

38. The sensor array of claim 37, wherein the sensors are provided on a common substrate.

39. The sensor array of claim 37, wherein the array is provided in a microtitre plate format.

40. A thermoelectric sensor comprising a substrate having a plurality of thermocouple sensing junctions formed thereon, the sensing junctions being arranged about a central region, corresponding thermocouple reference junctions coupled to the sensing junctions by electrical tracks extending radially outwardly of the central region from the sensing junctions, and a region of relatively low thermal mass provided adjacent at least that portion of the substrate bearing the sensing junctions.

41. A method of manufacturing a thermoelectric sensor for monitoring of biological samples, the method comprising the steps of: forming a plurality of sensing and reference junctions on a membrane located on a support; and removing a part of the support adjacent the sensing junctions to leave a membrane bearing the sensing junctions overlying a region of lower thermal mass.

42. The method of claim 41, further comprising the step of depositing a membrane on the support prior to forming the sensing and reference junctions thereon.

43. The method of claim 41, wherein the junctions are formed by deposition.

44. The method of claim 41, wherein the step of forming the junctions further comprises photolithography or electron beam lithography to define detailed features of the junctions.

45. The method of claim 41, wherein the step of removing a part of the support comprises back etching the support in a defined region.

46. The method of claim 41, further comprising the step of mounting a cover to the support to substantially enclose the region of lower thermal mass.

47. The method of claim 41, further comprising the step of depositing a substance over the junctions to form a titre chamber around the sensing junctions.

48. The method of claim 41, further comprising the step of coating the sensing junctions with a substance to promote cell adhesion thereto.

49. The method of claim 41, further comprising the step of coating the sensing junctions with a biochemically active substance.

50. The method of claims 41, further comprising the step of manufacturing additional sensors on a common support, to form a sensor array.

51. A method of screening test compounds for physiological effects on a biological sample, the method comprising the steps of: locating a biological sample on a thermoelectric sensor comprising a substrate having a plurality of thermocouple sensing junctions formed thereon, the sensing junctions being arranged about a central region, corresponding thermocouple reference junctions coupled to the sensing junctions, and a region of relatively low thermal mass provided adjacent at least that portion of the substrate bearing the sensing junctions; contacting the biological sample with a test compound; and monitoring thermal properties of the biological sample before and after contact, to determine any difference between the two states, a difference being indicative of a physiological effect of the test compound on said biological sample.

52. A method of high-throughput screening of test compounds for physiological effects on biological samples, the method comprising : locating one or more biological samples on each of a plurality of thermoelectric sensors forming an array, each sensor comprising a substrate having a plurality of thermocouple sensing junctions formed thereon, the sensing junctions being arranged about a central region, corresponding thermocouple reference junctions coupled to the sensing junctions, and a region of relatively low thermal mass provided adjacent at least that portion of the substrate bearing the sensing junctions; contacting a test compound with each of the biological samples; and monitoring thermal properties of the biological samples before and after contact, to determine any difference between the two states, a difference being indicative of a physiological effect of the test compound on said biological sample.

53. A method of monitoring the physiological activity of a biological sample, the method comprising the steps OF: locating a biological sample on a thermoelectric sensor, the sensor comprising a substrate having a plurality of thermocouple sensing junctions formed thereon, the sensing junctions being arranged about a central region, corresponding thermocouple reference junctions coupled to the sensing junctions, and a region of relatively low thermal mass provided adjacent at least that portion of the substrate bearing the sensing junctions; and monitoring thermal energy generated by the sample, the energy being indicative of physiological activity.

54. The sensor of claim 2, wherein the sensing junctions are arranged in a generally circular layout around a central region.

55. The sensor of claim 2, wherein the sensing junctions are spaced from the centre of the central region by a distance compatible with the size of a sample appropriate to lab-on-a-chip analysis, such as a single cell.

56. The sensor of claim 14, wherein the cavity is substantially sealed to restrict flow of gas therein.

57. The sensor of claim 20, wherein the membrane is less than 2 microns in thickness.

58. The sensor of claim 25, further comprising a titer chamber defining a region including the sensing junctions.

59. The sensor of claim 30 wherein the polymer is photopatternable.

60. The sensor array of claim 38, wherein the array is provided in a microtitre plate format.

61. The method of claim 42, wherein the junctions are formed by deposition.
